(19) United States
(12) Patent Application Publication
(10) Pub. No.: US 2024/0003006 A1
(43) Pub. Date: Jan. 4, 2024

(54) VAPORIZER, GAS SUPPLY APPARATUS, AND METHOD OF CONTROLLING GAS SUPPLY APPARATUS

(71) Applicant: Fujikin Incorporated, Osaka (JP)

(72) Inventors: Yuta AYAI, Yamanashi (JP); Keiji HIRAO, Osaka (JP)

(21) Appl. No.: 18/247,489

(22) PCT Filed: Sep. 27, 2021
(86) PCT No.: PCT/JP2021/035455

§ 371 Date: Mar. 31, 2023

(30) Foreign Application Priority Data
Oct. 7, 2020 (JP) 2020-169970

(51) Int. Cl. C23C 16/448; C23C 16/455; C23C 16/52

(52) U.S. Cl. CPC C23C 16/448; C23C 16/45561; C23C 16/52

(57) ABSTRACT

Provided are a vaporizer and a gas supply apparatus both of which are compact and capable of supplying gas at a high flow rate, and a method of controlling the gas supply apparatus. The vaporizer includes: a heat-exchanging section that is configured to heat a liquid raw material; and a vaporizing section that is configured to vaporize the heated liquid raw material to form a raw material gas. The heat-exchanging section includes: a branched section to which the liquid raw material is supplied and in which the liquid raw material is branched; and thin tubes each connected to the branched section.

### TECHNICAL FIELD

The present disclosure relates to a vaporizer, a gas supply apparatus, and a method of controlling the gas supply apparatus.

### BACKGROUND ART

Known is a substrate-processing system that vaporizes a liquid raw material and supplies a raw material gas to a film-forming apparatus.

Patent Document 1 discloses a vaporization system including: a vaporizer that vaporizes a liquid material; a supply rate controller that controls a supply rate of the liquid material to the vaporizer; and a manifold block inside which an internal flow path is formed, and that has a device mounting surface on which both the vaporizer and the supply rate controller are mounted, wherein, as a result of the vaporizer and the supply rate controller being mounted on the device mounting surface, the vaporizer and the supply rate controller are connected together via the flow path.

### CITATION LIST

### Patent Document

[Patent Document 1] Japanese Laid-Open Patent Publication No. 2016-122841

### SUMMARY OF INVENTION

### Technical Problem

In one aspect, the present disclosure provides: a vaporizer and a gas supply apparatus both of which are compact and capable of supplying gas at a high flow rate; and a method of controlling the gas supply apparatus.

### Solution to Problem

In order to achieve the above object, according to one embodiment, provided is a vaporizer including: a heat-exchanging section that is configured to heat a liquid raw material; and a vaporizing section that is configured to vaporize the heated liquid raw material to form a raw material gas. The heat-exchanging section includes: a branched section to which the liquid raw material is supplied and in which the liquid raw material is branched; and thin tubes each connected to the branched section.

### Advantageous Effects of Invention

According to one aspect, it is possible to provide: a vaporizer and a gas supply apparatus both of which are compact and capable of supplying gas at a high flow rate; and a method of controlling the gas supply apparatus.

### BRIEF DESCRIPTION OF DRAWINGS

FIG. 1 is one example of a configurational view of a substrate-processing system including a vaporizer according to a first embodiment.

FIG. 2A is one example of a perspective view of a thin tube and a vaporizing section in the vaporizer according to the first embodiment.

FIG. 2B is one example of a perspective view of a thin tube and a vaporizing section in the vaporizer according to the first embodiment.

FIG. 3 depicts exemplary graphs for describing a flow rate of a raw material gas, a pressure of a raw material gas, and control of a liquid supply valve.

FIG. 4A is one example of a cross-sectional view for describing the shape of a tube of the vaporizing section.

FIG. 4B is one example of a cross-sectional view for describing the shape of a tube of the vaporizing section.

FIG. 4C is one example of a cross-sectional view for describing the shape of a tube of the vaporizing section.

FIG. 5 is one example of a perspective view of a vaporizer according to a second embodiment.

FIG. 6 is one example of a cross-sectional view of a branched section of the vaporizer according to the second embodiment.

FIG. 7 is one example of a cross-sectional view of thin tubes and a vaporizing section of the vaporizer according to the second embodiment.

FIG. 8 is one example of a cross-sectional view of a vaporizer according to a third embodiment.

FIG. 9 is one example of a perspective view of a heat-exchanging section of the vaporizer according to the third embodiment.

### DESCRIPTION OF EMBODIMENTS

In the following, embodiments of the present disclosure will be described with reference to the drawings. In the drawings, the same elements are denoted by the same reference numerals and the description thereof may be omitted.

### First Embodiment

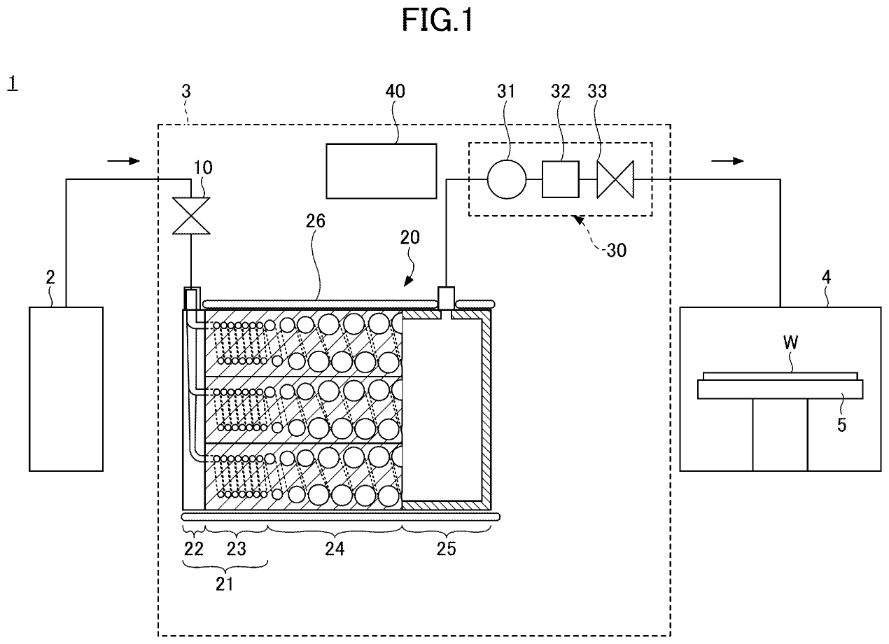

Referring to FIG. 1, a substrate-processing system 1 including a vaporizer 20 according to the first embodiment will be described. FIG. 1 is one example of a configurational view of the substrate-processing system 1 including the vaporizer 20 according to the first embodiment.

The substrate-processing system 1 includes a liquid raw material supply source 2, a liquid material vaporizing and supplying device 3, and a process chamber 4. The substrate-processing system 1 supplies a liquid raw material (a liquid precursor) that has been supplied from the liquid raw material supply source 2, to the liquid material vaporizing and supplying device 3. Also, the substrate-processing system 1 performs a desired process (e.g., film formation) on a substrate W placed on a stage 5 in the process chamber 4, by supplying a vaporized raw material gas to the process chamber 4. The vaporized raw material gas is obtained by vaporizing the liquid raw material in the liquid material vaporizing and supplying device 3. Note that, the liquid raw material supply source 2 and the liquid material vaporizing and supplying device 3 function as a gas supply apparatus that is configured to supply the raw material gas to the process chamber 4.

The liquid raw material supply source 2 holds the liquid raw material in reserve, and supplies the liquid raw material to the liquid material vaporizing and supplying device 3.

The liquid material vaporizing and supplying device 3 holds in reserve a vaporized raw material gas that is obtained by vaporizing the liquid raw material supplied from the liquid raw material supply source 2. Also, the liquid material vaporizing and supplying device 3 supplies the reserved raw material gas to the process chamber 4. The liquid material vaporizing and supplying device 3 includes a liquid supply valve 10, the vaporizer 20, a gas flow rate regulator 30, and a controller 40.

The liquid supply valve 10 is, for example, an open/close valve, and is provided in a supply path through which the liquid raw material is supplied from the liquid raw material supply source 2 to the liquid material vaporizing and supplying device 3. The liquid supply valve 10 is opened or closed under control by the controller 40.

The vaporizer 20 includes a heat-exchanging section 21, a vaporizing section 24, a fill tank 25, and a heater 26.

The heat-exchanging section 21 includes a branched section 22 and a plurality of thin tubes 23. The liquid raw material supplied from the liquid raw material supply source 2 flows through branched flow paths in the branched section 22, to the plurality of thin tubes 23. In the thin tubes 23, fine and long flow paths are formed. Also, the heat-exchanging section 21 is heated by the heater 26. The liquid raw material flowing through the thin tubes 23 is heat-exchanged with the thin tubes 23 heated by the heater 26, so that the liquid raw material is heated to a predetermined heat temperature. With such a configuration, the liquid raw material can be efficiently heated in a small space.

The vaporizing section 24 is connected to each of the plurality of thin tubes 23. In the vaporizing section 24, a flow path is formed such that the space (flow path) becomes larger from upstream to downstream. The vaporizing section 24 is formed, for example, so that the cross-sectional area of the flow path becomes larger from upstream to downstream. Also, for example, the vaporizing section 24 is formed such that the inner diameter of the flow path becomes larger from upstream to downstream. Also, for example, the vaporizing section 24 is formed such that the flow path becomes wider in a tapered shape from upstream to downstream. Also, the vaporizing section 24 is heated by the heater 26.

The liquid raw material heated to the heat temperature in the thin tubes 23 is supplied to the vaporizing section 24. In the vaporizing section 24, which is formed such that the space (flow path) becomes larger from upstream to downstream, the pressure in the flow path of the vaporizing section 24 is reduced to be equal to or lower than the vapor pressure at the heat temperature. Thereby, the liquid raw material undergoes forced convection boiling in the flow path of the vaporizing section 24, and the liquid raw material vaporizes to form a raw material gas.

The vaporizer 20 has such a structure that the flow path of the thin tubes 23 and the vaporizing section 24 involves reduced loss in pressure and is capable of further reducing the pressure of the liquid raw material. This makes it possible to reduce a heat temperature for vaporization of the liquid raw material. Thereby, it is possible to suppress degradation of the raw material due to heat.

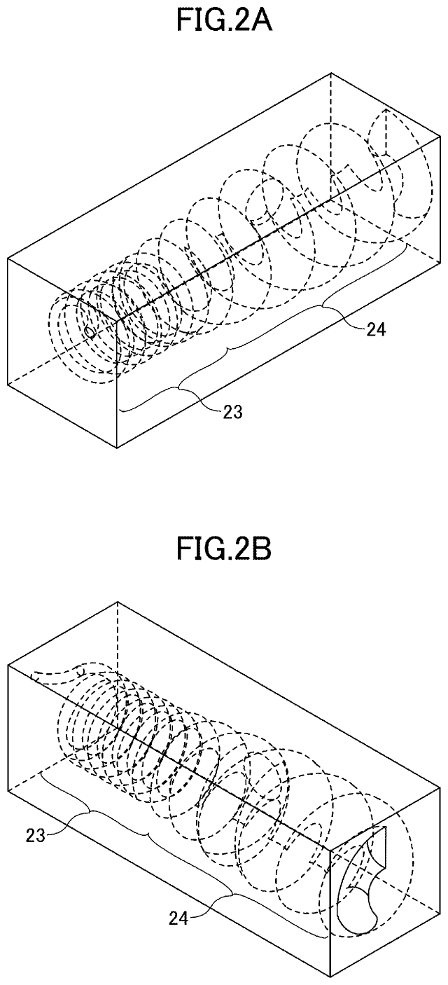

FIG. 2A and FIG. 2B are each one example of a perspective view of the thin tube 23 and the vaporizing section 24 in the vaporizer 20 according to the first embodiment. FIG. 2A is a perspective view from the side of the thin tube 23. FIG. 2B is a perspective view from the side of the vaporizing section 24.

In the examples illustrated in FIG. 2A and FIG. 2B, the flow path of the thin tube 23 and the vaporizing section 24 is helically formed (as a helical curve). Also, the cross-sectional area of the flow path of the thin tube 23 is constant. Meanwhile, the cross-sectional area of the flow path of the vaporizing section 24 is larger downstream than upstream.

As described above, in the vaporizer 20 according to the first embodiment, the flow path is formed to have a spiral shape. This makes it possible to form a flow path in a space having a small occupied area, where the flow path is long and involves reduced loss in pressure. Note that, the spiral flow path of the thin tube 23 and/or the vaporizing section 24 may be shaped integrally or separately through, for example, additive manufacturing (using a 3D printer), such as powder sintering. Alternatively, the spiral flow path may be a plate members-stacked structure obtained by stacking a plurality of plate members each having a hole (hole portion) and/or a groove (groove portion) on top of one another, followed by jointing. By employing such a structure, it is possible to readily form the thin tube 23 and the vaporizing section 24 each having a complicated flow path therein.

The raw material gas vaporized in the vaporizing section 24 is charged into the fill tank 25. Also, the fill tank 25 is heated by the heater 26. Note that, a tube from the outlet of the fill tank 25 to the gas flow rate regulator 30 or a tube from the outlet of the fill tank 25 to the process chamber 4 may be heated to a temperature higher than the temperature of the fill tank 25, in order to prevent the raw material gas from returning to liquid.

The gas flow rate regulator 30 includes a pressure sensor 31, a flow rate sensor 32, and a flow rate control valve 33.

The pressure sensor 31 detects the pressure of the raw material gas. Note that, although FIG. 1 illustrates the pressure sensor 31 as one provided in the supply path through which the raw material gas is supplied from the vaporizer 20 to the process chamber 4, there is no limitation on the position thereof, and the pressure sensor 31 may be provided in, for example, the fill tank 25. The pressure of the raw material gas that has been detected by the pressure sensor 31 is output to the controller 40.

The flow rate sensor 32 detects the flow rate of the raw material gas. Note that, as illustrated in FIG. 1, the flow rate sensor 32 is provided in the supply path through which the raw material gas is supplied from the vaporizer 20 to the process chamber 4. The flow rate of the raw material gas that has been detected by the flow rate sensor 32 is output to the controller 40.

The flow rate control valve 33 is provided in the supply path through which the raw material gas is supplied from the vaporizer 20 to the process chamber 4. The flow rate control valve 33 controls the flow rate of the raw material gas to be supplied from the vaporizer 20 to the process chamber 4. The degree of opening (flow rate) of the flow rate control valve 33 is controlled by the controller 40.

The controller 40 controls opening or closing of the liquid supply valve 10 based on the pressure of the raw material gas detected by the pressure sensor 31. Also, the controller 40 controls opening or closing of the flow rate control valve 33 based on the flow rate of the raw material gas detected by the flow rate sensor 32.

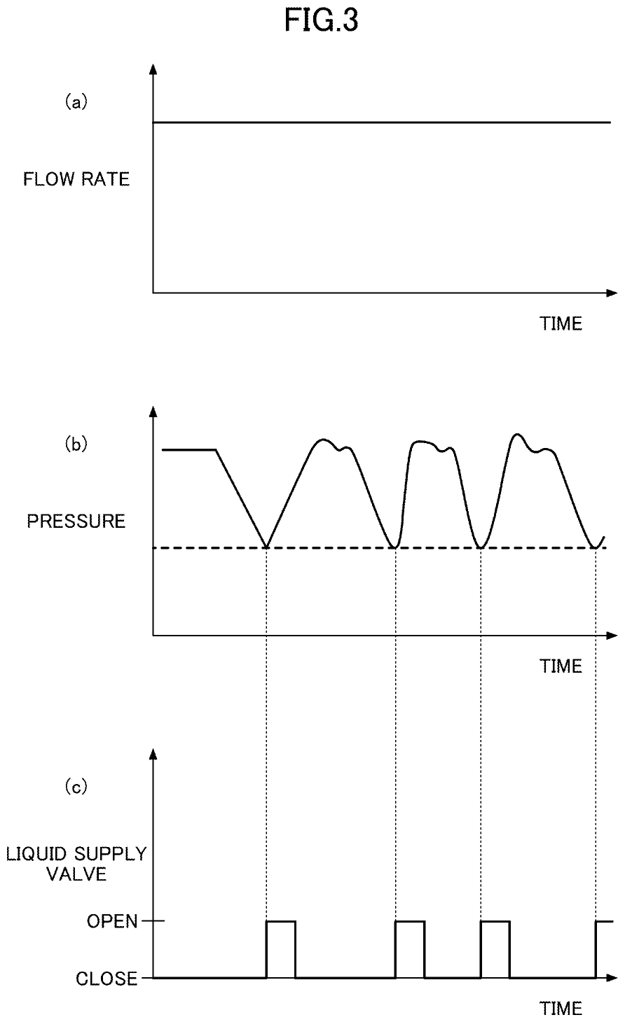

Here, referring to FIG. 3, one example of control of the liquid supply valve 10 by the controller 40 will be described. FIG. 3 depicts exemplary graphs for describing the flow rate of the raw material gas, the pressure of the raw material gas, and the control of the liquid supply valve 10. FIG. 3(a) is a graph describing change over time in the flow rate of the raw material gas. FIG. 3(b) is a graph describing change over time in the pressure of the raw material gas. FIG. 3(c) is a graph describing change over time in the opening or closing of the liquid supply valve 10.

As illustrated in FIG. 3(a), the controller 40 controls the opening or closing of the flow rate control valve 33 based on the flow rate of the raw material gas detected by the flow rate sensor 32. Thereby, even if the pressure of the raw material gas in the fill tank 25 varies, it is possible to supply the raw material gas to the process chamber 4 at a constant flow rate.

Also, by supplying the raw material gas to the process chamber 4 from the fill tank 25, as illustrated in FIG. 3(b), the pressure of the raw material gas decreases. The controller 40 controls the opening or closing of the liquid supply valve 10 based on the pressure of the raw material gas detected by the pressure sensor 31. Once the pressure of the raw material gas detected by the pressure sensor 31 reaches a predetermined threshold (indicated by a dashed line), the controller 40 opens the liquid supply valve 10. After a predetermined time has passed, the controller 40 closes the liquid supply valve 10.

Thereby, the liquid raw material is supplied to the vaporizer 20, and the vaporized raw material gas is charged into the fill tank 25. This makes it possible to maintain the supply pressure in operation of the flow rate control valve 33. Note that, the predetermined time for which the liquid supply valve 10 is opened may be set based on such a liquid quantity that the liquid raw material supplied to the vaporizing section 24 can all be vaporized.

Note that, although FIG. 1 illustrates an example in which the liquid supply valve 10 is disposed between the branched section 22 and the liquid raw material supply source 2, the liquid supply valve may be disposed in each of the lines that are branched in the branched section.

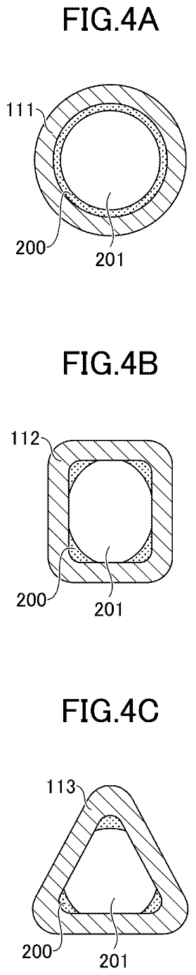

Next, referring to FIG. 4A to FIG. 4C, the shapes of the tube of the vaporizing section 24 will be described. FIG. 4A to FIG. 4C are each one example of the cross-sectional view for describing the shape of the tube of the vaporizing section 24.

FIG. 4A is one example of a view for describing a state of the raw material in a cylindrical tube 111. As illustrated in FIG. 4A, the raw material flowing through the vaporizing section 24 (tube 111) is in a state of a gas-liquid mixture (slug flow, annular flow) of a liquid raw material 200 and a raw material gas 201. In the cylindrical tube 111, the liquid raw material 200 is positioned so as to cover the inner wall face of the tube 111. Therefore, the raw material gas 201 and the wall face of the tube 111 do not directly contact each other.

FIG. 4B is one example of a view for describing a state of the raw material in a tetragonal tube 112. Similarly, the raw material flowing through the vaporizing section 24 (tube 112) is in a state of a gas-liquid mixture (slug flow, annular flow) of the liquid raw material 200 and the raw material gas 201. Here, in the tetragonal tube 112, the liquid raw material 200 is positioned at the corners of the inner wall face of the tube 112. Therefore, in the vicinity of the central portion of each of the sides of the tetragonal shape, the raw material gas 201 and the wall face of the tube 112 directly contact each other.

FIG. 4C is one example of a view for describing a state of the raw material in a triangular tube 113. Similarly, the raw material flowing through the vaporizing section 24 (tube 113) is in a state of a gas-liquid mixture (slug flow, annular flow) of the liquid raw material 200 and the raw material gas 201. Here, in the triangular tube 113, the liquid raw material 200 is positioned at the corners of the inner wall face of the tube 113. Therefore, in the vicinity of the central portion of each of the sides of the triangular shape, the raw material gas 201 and the wall face of the tube 113 directly contact each other.

As described above, the tube of the vaporizing section 24 may have a polygonal cross-sectional shape. Here, the heat exchange efficiency between the heated tube wall face and the gaseous raw material is higher than the heat exchange efficiency between the heated tube wall face and the liquid raw material. Therefore, as illustrated in FIG. 4B and FIG. 4C, by providing the corners in the cross-sectional shape of the tube, it is possible to increase the contact area between the heated tube wall face and the gaseous raw material, and to enhance the heat exchange performance.

### Second Embodiment

Next, a substrate-processing system including a vaporizer 20A according to the second embodiment will be described. The substrate-processing system according to the second embodiment differs from the substrate-processing system 1 according to the first embodiment (see FIG. 1) in terms of the configuration of the vaporizer 20A. The other members are the same therebetween, and the description thereof will be omitted.

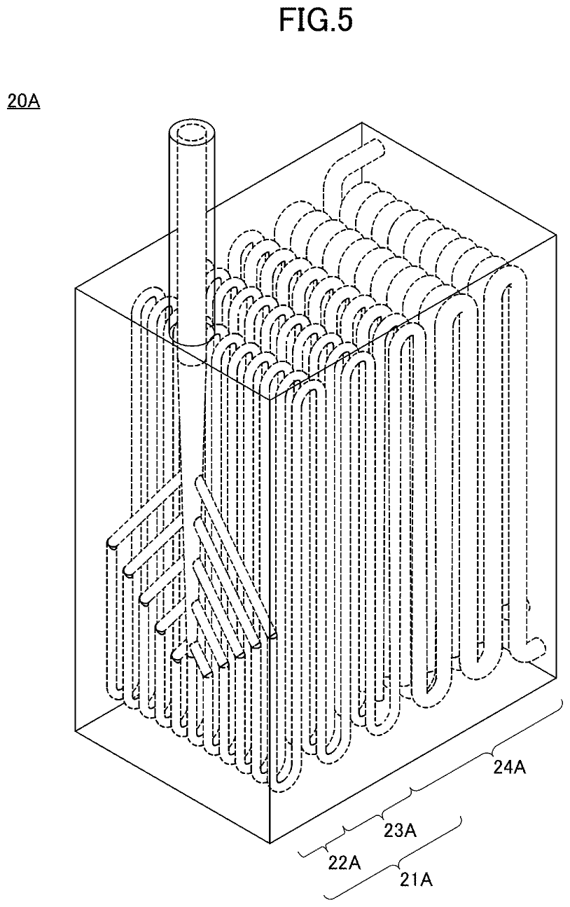

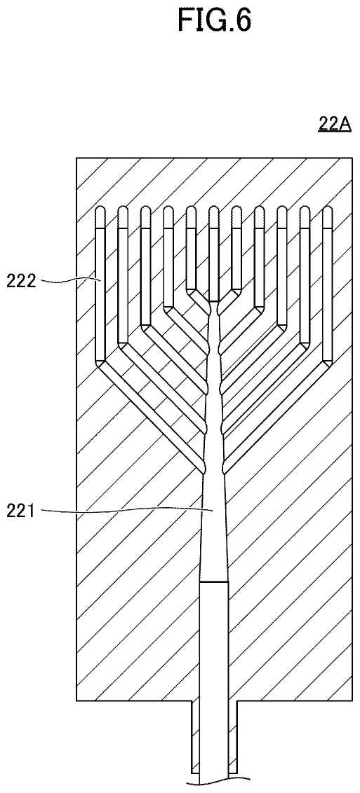

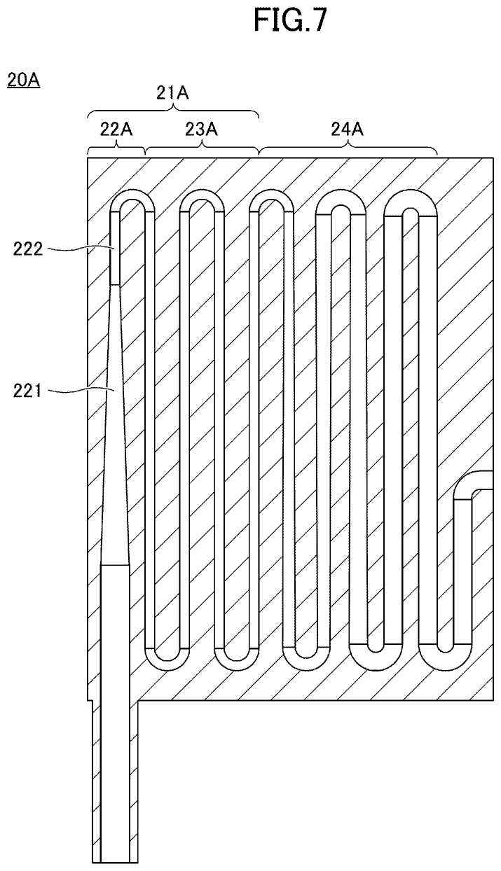

Referring to FIG. 5 to FIG. 7, the vaporizer 20A according to the second embodiment will be described. FIG. 5 is one example of a perspective view of the vaporizer 20A according to the second embodiment. FIG. 6 is one example of a cross-sectional view of a branched section 22A of the vaporizer 20A according to the second embodiment. FIG. 7 is one example of a cross-sectional view of a thin tube 23A and a vaporizing section 24A of the vaporizer 20A according to the second embodiment. Note that, in FIG. 5 to FIG. 7, the fill tank 25 and the heater 26 are not illustrated.

The vaporizer 20A includes a heat-exchanging section 21A, the vaporizing section 24A, a fill tank (not illustrated), and a heater (not illustrated).

The heat-exchanging section 21A includes the branched section 22A and a plurality of thin tubes 23A. As illustrated in FIG. 6, the flow paths formed in the branched section 22A include a large-diameter portion 221 and small-diameter portions 222 branched from the large-diameter portion 221. As illustrated in FIG. 7, the small-diameter portions 222 are connected to the thin tubes 23A. Also, the thin tube 23A is connected to the vaporizing section 24A.

The liquid raw material supplied from the liquid raw material supply source 2 is branched to the plurality of thin tubes 23A in the branched section 22A. Also, the heat-exchanging section 21A is heated by a heater. The liquid raw material flowing through the thin tube 23A is heat-exchanged with the thin tube 23A heated by the heater, so that the liquid raw material is heated to a predetermined heat temperature. With such a configuration, the liquid raw material can be efficiently heated in a small space.

The vaporizing section 24A is connected to each of the plurality of thin tubes 23A. In the vaporizing section 24A, a flow path is formed such that the space (flow path) becomes larger from upstream to downstream. The vaporizing section 24A is formed, for example, so that the cross-sectional area of the flow path becomes larger from upstream to downstream. Also, for example, the vaporizing section 24 is formed such that the inner diameter of the flow path becomes larger from upstream to downstream. Also, for example, the vaporizing section 24 is formed such that the flow path becomes wider in a tapered shape from upstream to downstream. Also, the vaporizing section 24 is heated by the heater 26.

The liquid raw material heated to the heat temperature by the thin tubes 23A is supplied to the vaporizing section 24A. In the vaporizing section 24A, which is formed such that the space (flow path) becomes larger from upstream to downstream, the pressure in the flow path of the vaporizing section 24A is reduced to be equal to or lower than the vapor pressure at the heat temperature. Thereby, the liquid raw material undergoes forced convection boiling in the flow path of the vaporizing section 24A, and the liquid raw material vaporizes to form a raw material gas.

As described above, the vaporizer 20A according to the second embodiment forms a flow path having a shape of the letter U. This makes it possible to form a fine long flow path having such a shape as to involve reduced loss in pressure. Note that, the U-shaped flow path of the thin tube 23 and the vaporizing section 24 may be shaped by, for example, bonding plates each having a recessed portion.

### Third Embodiment

Next, a substrate-processing system including a vaporizer 20B according to the third embodiment will be described. The substrate-processing system according to the third embodiment differs from the substrate-processing system 1 according to the first embodiment (see FIG. 1) in terms of the configuration of the vaporizer 20B. The other members are the same therebetween, and the description thereof will be omitted.

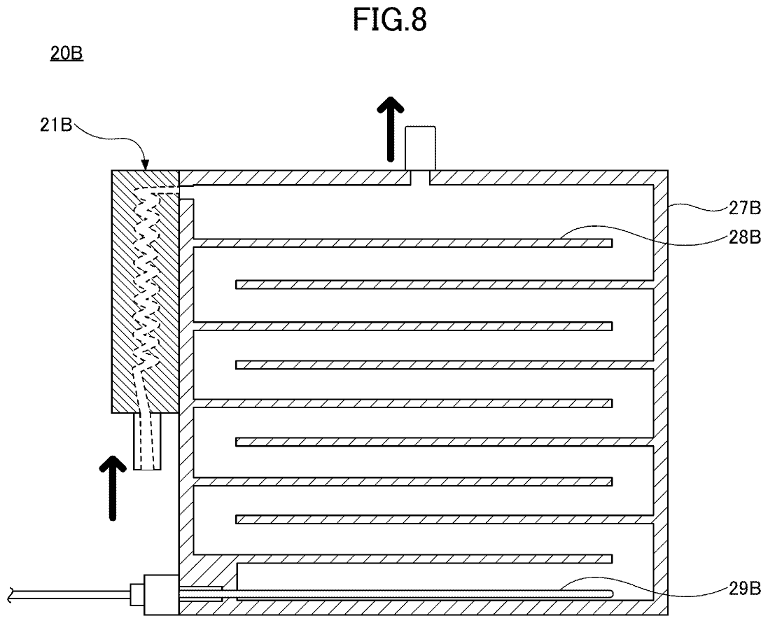

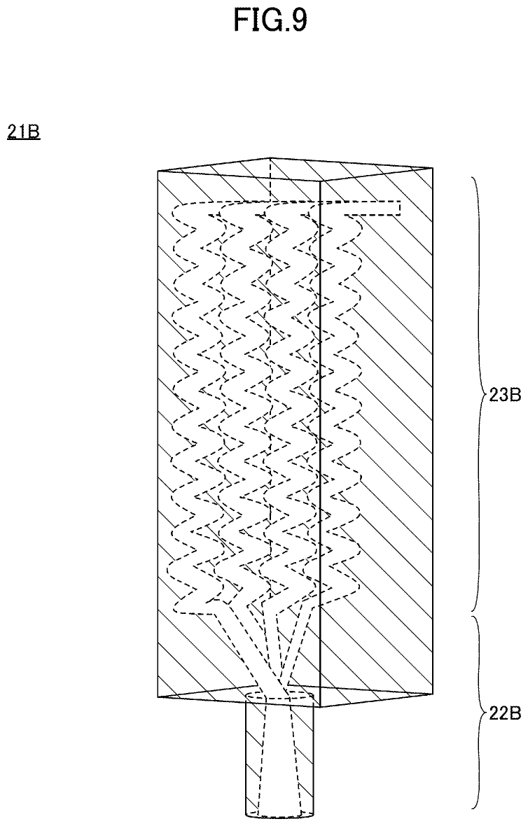

Referring to FIG. 8 and FIG. 9, a vaporizer 20B according to the third embodiment will be described. FIG. 8 is one example of a cross-sectional view of the vaporizer 20B according to the third embodiment. FIG. 9 is one example of a perspective view of a heat-exchanging section 21B of the vaporizer 20B according to the third embodiment. Note that, in FIG. 8 and FIG. 9, a heater is omitted.

The vaporizer 20B includes the heat-exchanging section 21B, a vaporizing chamber 27B, and a heater (not illustrated). The vaporizing chamber 27B has multi-stepped trays 28B. Also, a sensor 29B is provided in the lowest step of the vaporizing chamber 27B.

As illustrated in FIG. 9, the heat-exchanging section 21B includes a branched section 22B and a plurality of thin tubes 23B. Note that, in the example illustrated in FIG. 9, the thin tubes 23B form spiral flow paths. This makes it possible to form a flow path in a space having a small occupied area, where the flow path is long and involves reduced loss in pressure.

The heat-exchanging section 21B is heated by the heater. The liquid raw material supplied to the heat-exchanging section 21B is heated to a predetermined heat temperature. The heated liquid raw material is supplied to the vaporizing chamber 27B. Note that, the flow path of the thin tubes 23B of the heat-exchanging section 21B has been described taking the spiral flow path as an example. The shape of the flow path is not limited thereto, and may be a U shape.

The vaporizing chamber 27B has a larger space than the thin tube 23B. Thereby, the liquid raw material supplied to the vaporizing chamber 27B is reduced in pressure and boiled (vaporized). Also, the liquid raw material supplied to the vaporizing chamber 27B spreads on the trays 28B. The vaporizing chamber 27B and the trays 28B are heated by the heater. Thereby, the liquid raw material on the trays 28 vaporize. The vaporized raw material gas is charged into the vaporizing chamber 27B. In other words, the vaporizing chamber 27B also functions as a fill tank.

As illustrated in FIG. 8, the trays 28B are alternatingly disposed. The liquid raw material having flowed into the vaporizing chamber 27B flows into the tray 28B of one of the steps, and then flows into the tray 28B of the next step from the end of the tray 28B of the one of the steps. In this manner, the liquid raw material is supplied in order from the top step.

The sensor 29B provided in the lowest step of the vaporizing chamber 27B is a sensor that detects a liquid. In response to the detection of the liquid by the sensor 29B, the controller 40 controls the liquid supply valve 10 (see FIG. 1) so as to be closed. Thereby, the supply of an excess amount of the liquid raw material to the tray 28B of the vaporizing chamber 27B is prevented, thereby facilitating efficient vaporization of the liquid raw material.

While the substrate-processing systems including the vaporizers 20 to 20B according to the first to third embodiments have been described above, the present disclosure is not limited to, for example, the above embodiments, and various modifications and changes are possible within the scope of the subject matter as recited in the claims.

Note that, the present application claims priority to Japanese Patent Application No. 2020-169970, filed Oct. 7, 2020. The contents of this Japanese Patent Application are incorporated herein by reference in their entirety.

### DESCRIPTION OF THE REFERENCE NUMERAL

1 Substrate-processing system
2 Liquid raw material supply source
3 Liquid material vaporizing and supplying device
4 Process chamber
5 Stage
10 Liquid supply valve
20 Vaporizer
21 Heat-exchanging section
22 Branched section
23 Thin tube
24 Vaporizing section
25 Fill tank
26 Heater
30 Gas flow rate regulator
31 Pressure sensor
32 Flow rate sensor
33 Flow rate control valve
40 Controller
111 to 113 Tube
200 Liquid raw material
201 Raw material gas

1. A vaporizer, comprising:
a heat-exchanging section that is configured to heat a liquid raw material; and
a vaporizing section that is configured to vaporize the heated liquid raw material to form a raw material gas,
the heat-exchanging section including
a branched section to which the liquid raw material is supplied and in which the liquid raw material is branched, and
tubes each connected to the branched section.

2. The vaporizer according to claim 1, wherein the tubes are formed in a helical shape or in a U shape.

3. (canceled)

4. The vaporizer according to claim 1, wherein a cross-sectional area of a downstream flow path in the vaporizing section is larger than a cross-sectional area of an upstream flow path in the vaporizing section.

5. The vaporizer according to claim 1, wherein the vaporizing section, the tubes, or both are formed from a stack of a plurality of plate members each having a hole, a groove, or both.

6. The vaporizer according to claim 1, further comprising:
a tank connected to the vaporizing section, wherein the raw material gas from the vaporizing section is charged into the tank.

7. The vaporizer according to claim 1, wherein:
the vaporizing section includes a plurality of trays provided in multiple steps; and
a liquid heated in the heat-exchanging section flows into a first tray of one of the steps, and flows into a second tray of a next step from the first tray of the one of the steps.

8. The vaporizer according to claim 7, further comprising:
a liquid sensor that is provided in any tray of the plurality of trays other than the first tray and configured to detect inflow of the liquid.

9. A gas supply apparatus, comprising:
the vaporizer of claim 1;
a liquid raw material supply source that is configured to supply the liquid raw material to the vaporizer;
a liquid supply valve that is provided in a supply path extending from the liquid raw material supply source to the vaporizer;
a pressure detector that is configured to detect a pressure of the raw material gas vaporized in the vaporizer; and
a controller,
wherein the controller is configured to control the liquid supply valve based on a detection result of the pressure detector.

10. The gas supply apparatus according to claim 9, wherein in response to the pressure detected by the pressure detector being equal to or lower than a predetermined pressure, the controller opens the liquid supply valve for a predetermined time.

11. A gas supply apparatus, comprising:
the vaporizer of claim 8;
a liquid raw material supply source that is configured to supply the liquid raw material to the vaporizer;
a liquid supply valve that is provided in a supply path extending from the liquid raw material supply source to the vaporizer; and
a controller,
wherein in response to detection of the liquid raw material by the liquid sensor, the controller closes the liquid supply valve.

12. A method of controlling a gas supply apparatus that includes the vaporizer of claim 1, a liquid raw material supply source that is configured to supply a liquid to the vaporizer, a liquid supply valve that is provided in a supply path extending from the liquid raw material supply source to the vaporizer, and a pressure detector that is configured to detect a pressure of a raw material gas vaporized in the vaporizer, the method comprising:
controlling the liquid supply valve based on a detection result of the pressure detector.

13. The method of controlling the gas supply apparatus according to claim 12, wherein in response to the pressure detected by the pressure detector being equal to or lower than a predetermined pressure, the liquid supply valve is opened for a predetermined time.

14. A method of controlling a gas supply apparatus that includes the vaporizer of claim 8, a liquid raw material supply source that is configured to supply the liquid raw material to the vaporizer, and a liquid supply valve that is provided in a supply path extending from the liquid raw material supply source to the vaporizer, the method comprising:
closing the liquid supply valve in response to detection of the liquid raw material by the liquid sensor.

15. The vaporizer according to claim 2, wherein a cross-sectional area of a downstream flow path in the vaporizing section is larger than a cross-sectional area of an upstream flow path in the vaporizing section.

16. The vaporizer according to claim 2, wherein the vaporizing section, the tubes, or both are formed from a stack of a plurality of plate members each having a hole, a groove, or both.

17. The vaporizer according to claim 4, wherein the vaporizing section, the tubes, or both are formed from a stack of a plurality of plate members each having a hole, a groove, or both.

18. The vaporizer according to claim 2, further comprising:
a tank connected to the vaporizing section, wherein the raw material gas from the vaporizing section is charged into the tank.

19. The vaporizer according to claim 4, further comprising:
a tank connected to the vaporizing section, wherein the raw material gas from the vaporizing section is charged into the tank.

20. The vaporizer according to claim 5, further comprising:
a tank connected to the vaporizing section, wherein the raw material gas from the vaporizing section is charged into the tank.

21. The vaporizer according to claim 2, wherein:
the vaporizing section includes a plurality of trays provided in multiple steps; and
a liquid heated in the heat-exchanging section flows into a first tray of one of the steps, and flows into a second tray of a next step from the first tray of the one of the steps.
